(19) United States
(12) Patent Application Publication
(10) Pub. No.: US 2006/0154484 A1
(43) Pub. Date: Jul. 13, 2006

(54) Method of removing a low-k layer and method of recycling a wafer using the same

(76) Inventors: Dong-Won Hwang, Gyeonggi-do (KR); Yang-Koo Lee, Gyeonggi-do (KR); Dong-Chul Heo, Gyeonggi-do (KR); Pil-Kwon Jun, Gyeonggi-do (KR); Kwang-Shin Lim, Gyeonggi-do (KR); Sang-Eon Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/330,803

(22) Filed: Jan. 11, 2006

(30) Foreign Application Priority Data
Jan. 12, 2005 (KR) 2005-2991

(51) Int. Cl. H01L 21/302; H01L 21/461

(52) U.S. Cl. 438/689

(57) ABSTRACT

In one embodiment, a method of removing a low-k layer at a low cost and a method of recycling a wafer using the same, is described. A fluoride treatment is performed on the low-k layer formed on an object using an aqueous hydrogen fluoride solution, and the low-k layer is removed from the object. The Si—O bond in the low-k layer is broken due to an aqueous hydrogen fluoride solution, so that the low-k layer is easily removed from the wafer. Accordingly, the wafer may be recycled at a low cost, thereby improving manufacturing productivity of a semiconductor.

### CROSS REFERENCES TO RELATED APPLICATIONS

This application claims priority from Korean Patent Application No. 2005-2991 filed on Jan. 12, 2005, the content of which is herein incorporated by reference in its entirety.

### BACKGROUND OF THE INVENTION

1. Field of the Invention

The present invention relates to a method of removing a low-k layer of which its dielectric constant is very low, and a method of recycling a wafer using the same. More particularly, the present invention relates to a method of removing a low-k layer applicable to a recycle process for a wafer and a method of recycling a wafer using the same.

2. Description of the Related Art

As information media, such as computers and other electronics, become widely used, the semiconductor industry makes great strides in developing information media products. Functionally, semiconductor devices with a large storage capacity are required to operate at a very high speed. Accordingly, the operation speed of semiconductor devices has increased due to improved degrees of integration, reliability and response capabilities.

Conductive lines in semiconductor structures have been insulated from their surroundings by an insulation layer such as a silicon oxide layer. However, because the semiconductor device operates at a high speed and is scaled down in size, an operation frequency of the device is increased and the space between the conductive lines adjacent to each other is decreased. As a result, a parasitic capacitance between conductive lines increases and the operation speed of the device is decreased. For the above reasons, an insulation material having a low dielectric constant, for example, a low-k material, is used for the insulation layer.

The capacitance of a capacitor is proportional to the dielectric constant k of a dielectric layer of the capacitor. The dielectric layer of a capacitor in a conventional IC may comprise a silicon oxide such as silicon dioxide (SiO2), which has a dielectric constant of about 4.0. However, when the silicon oxide layer is used as an insulation layer for insulating a conductive line in a semiconductor device of which an operation frequency is high and of which a line width is small, conductive lines may not be well-insulated from one another and the parasitic capacitance between the lines necessarily increases. Accordingly, an intensive topic of research has been directed to developing a new material having a dielectric constant lower than that of silicon dioxide (SiO2) to reduce the parasitic capacitance between the conductive lines.

Up to now, various materials having a dielectric constant lower than that of silicon dioxide (SiO2) have been suggested, such as organic compounds. In general, a material of which a dielectric constant k is below about 3 is widely known as a low dielectric constant material and is referred to as a low-k material hereinafter. A thin layer or film comprising the low-k material is also referred to as a low-k layer hereinafter. An example of a low-k material includes a carbon (C) doped silicon oxide having a dielectric constant from about 2.8 to about 2.9. In general, a silicon oxide combined with carbon is deposited onto a surface of a wafer by a chemical vapor deposition (CVD) process.

After detecting a process failure on a wafer or a dummy wafer in a manufacture process for a semiconductor device, the wafer having the process failure is usually recycled. In particular, U.S. Pat. No. 6,693,047 discloses a method of removing a carbon doped silicon oxide from a wafer to recycle the wafer. According to the above U.S. patent, a low-k layer comprising the carbon doped silicon oxide is oxidized using a hot furnace of a high temperature or plasma, so that the carbon doped silicon oxide in the low-k layer is transformed into a silicon oxide. Then, the silicon oxide layer is removed from the wafer using an aqueous hydrogen fluoride (HF) solution, removing the low-k layer from the wafer.

However, the above removal method has problems in that the hot furnace or plasma is difficult to apply to a mass production and is high cost. Thus, there is a need for an improved method of recycling a wafer on which a low-k layer is formed.

### SUMMARY

Accordingly, embodiments of the present invention provide a method of removing a low-k layer at a low cost.

Embodiments of the present invention also provide a method of recycling a wafer using the above method of removing a low-k layer.

According to an aspect of the present invention, there is provided a method of removing a low-k layer from an object. A fluoride treatment is performed on the low-k layer formed on the object using an aqueous hydrogen fluoride solution. Then, the low-k layer is removed from the object. In some embodiments of the present invention, the low-k layer comprises an organic silicon compound. In some embodiments, the low-k layer is removed from the object by a chemical polishing process using a solution having a base, a physical polishing process including a brushing process and both the chemical polishing process and the physical polishing process.

According to another aspect of the present invention, there is provided a method of recycling a wafer. A fluoride treatment is performed on a low-k layer formed on a wafer using an aqueous hydrogen fluoride solution, and the low-k layer is removed from the wafer by one of a chemical polishing process, a physical polishing process and both the chemical polishing process and the physical polishing process.

According to some embodiments of the present invention, a wafer is recycled by removal of a low-k layer from the wafer. The Si—O bond in the low-k layer is broken or is on the verge of breaking the bond due to an aqueous hydrogen fluoride solution, so that the low-k layer is easily removed from the wafer in a subsequent process. Accordingly, the wafer may be recycled at a low cost without any high temperature processes, thereby improving manufacturing productivity of a semiconductor.

### BRIEF DESCRIPTION OF THE DRAWINGS

The above and other features and advantages of the present invention will become readily apparent by reference to the following detailed description when considering in conjunction with the accompanying drawings, in which:

FIG. 1 is a flow diagram illustrating a method of removing a low-k layer according to an example embodiment of the present invention;

FIG. 2 is a graph showing a reactivity of the low-k layer and hydrogen fluoride in relation to a concentration of an aqueous hydrogen fluoride solution;

FIGS. 3 to 5 are cross-sectional views illustrating processing steps for a method of recycling a wafer according to an example embodiment of the present invention;

FIG. 6 is an electron microscope photograph showing a sample wafer on which a low-k layer is formed; and

FIG. 7 is an electron microscope photograph showing the sample wafer from which the low-k layer is removed in accordance with the same process as described with reference to FIG. 1.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Removing a Low-k Layer

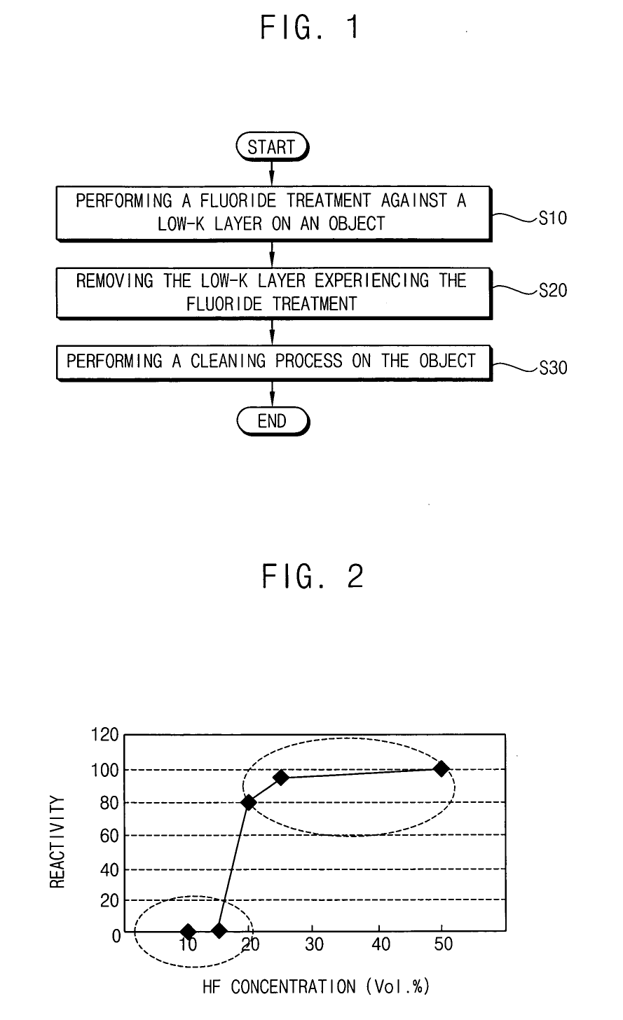

FIG. 1 is a flow diagram illustrating a method of removing a low-k layer according to an example embodiment of the present invention.

Referring to FIG. 1, a fluoride treatment is performed on a low-k layer on an object (step S10). For example, an aqueous hydrogen fluoride solution is supplied to the low-k layer on the object. The low-k layer may comprise an organic silicon compound. Examples of the organic silicon compound include carbon doped silicon oxide (SiCOH), hydrogenated silicon carbide, etc. These can be used alone or in combinations thereof.

FIG. 2 is a graph showing a reactivity of the low-k layer and hydrogen fluoride in relation to the concentration of an aqueous hydrogen fluoride solution.

Referring to FIG. 2, the reactivity of carbon doped silicon oxide and hydrogen fluoride is decisively varied with the concentration of the aqueous hydrogen fluoride solution. In particular, when the concentration of the aqueous hydrogen fluoride solution is no less than about 20% by volume, at least about 80% of carbon doped silicon oxide is reacted with hydrogen fluoride. Further, when the concentration of the aqueous hydrogen fluoride solution is about 30% by volume, almost all the carbon doped silicon oxide is reacted with hydrogen fluoride. In contrast, when the concentration of the aqueous hydrogen fluoride solution is below about 20% by volume, the carbon doped silicon oxide is much less reacted with hydrogen fluoride.

When the concentration of the aqueous hydrogen fluoride solution is below about 20% by volume, chemical reactions expressed as the following chemical equations (1) and (2) are predominant in the solution.
HF→H⁺+F⁻ (1)
HF+F⁻→HF₂⁻ (2)
In the aqueous hydrogen fluoride solution having the concentration below about 20% by volume, almost all the hydrogen fluoride is changed into ions. Accordingly, when an insulation layer comprising a silicon oxide such as silicon dioxide (SiO2) is wet etched away using the aqueous hydrogen fluoride solution as an etchant, a chemical bonding between silicon and oxygen (referred to as an Si—O bond) is broken due to the electron donating ability of the ions when the concentration of the aqueous hydrogen fluoride solution is below about 20% by volume.
When the concentration of the aqueous hydrogen fluoride solution is above about 20% by volume, chemical reactions expressed as following chemical equations (3) and (4) are predominant in the solution.
HF+H₂O→H₃O⁺+F⁻ (3)
HF+HF⁻→H₂F⁺+F⁻ (4)
In the aqueous hydrogen fluoride solution having a concentration above about 20% by volume, almost all the hydrogen fluoride is changed into ions. Accordingly, when an insulation layer comprising a silicon oxide such as silicon dioxide (SiO2) is wet etched away using the aqueous hydrogen fluoride solution as an etchant, the Si—O bond is broken due to the proton donating ability of the ions when the concentration of the aqueous hydrogen fluoride solution is above about 20% by volume.

Carbon doped silicon oxide (SiCOH) is structurally based on the Si—O bond as shown in the following structural formula of SiCOH, so that ions can react with carbon doped silicon oxide (SiCOH).

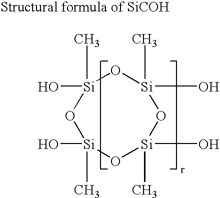

However, only HF₂⁻ ions react with carbon doped silicon oxide (SiCOH) due to a steric repulsion force caused by a methyl group in carbon doped silicon oxide (SiCOH).

As shown in FIG. 2, when the concentration of the aqueous hydrogen fluoride solution is below about 20% by volume, the Si—O bond in a low-k layer is scarcely broken, despite the fluoride treatment on the low-k layer. Accordingly, the concentration of the aqueous hydrogen fluoride solution is in a range of from about 20% by volume to about 100% by volume, and more particularly, in a range of from about 30% by volume to about 90% by volume. In the present embodiment, the concentration of the aqueous hydrogen fluoride solution ranges from about 30% by volume to about 50% by volume.

The fluoride treatment on a low-k layer includes an immersion of an object on which the low-k layer is formed into an aqueous hydrogen fluoride solution.

When the aqueous hydrogen fluoride solution is at a temperature below about 20° C., the Si—O bond is scarcely broken in the low-k layer because hydrogen fluoride is not sufficiently activated. When the aqueous hydrogen fluoride solution is at a temperature above about 60° C., the manufacturing cost becomes very high. In addition, the hot aqueous hydrogen fluoride solution at a temperature above about 60° C. is difficult to apply to a practical process. For those reasons, the aqueous hydrogen fluoride solution is at a temperature of about 20° C. to about 60° C.

When the low-k layer is immersed in the aqueous hydrogen fluoride solution for a time of less than about one minute, the Si—O bond is not sufficiently broken in the low-k layer due to a short reaction time, so that the low-k layer is hardly removed from the object in a subsequent process. When the low-k layer is immersed in the aqueous hydrogen fluoride solution for a time above about thirty minutes, the object itself may be damaged by the aqueous hydrogen fluoride solution. Accordingly, the low-k layer is immersed in the aqueous hydrogen fluoride solution for a time in a range of from about one minute to about thirty minutes.

Referring again to FIG. 1, the low-k layer on which the fluoride treatment is performed is removed from the object (step S20). The low-k layer may be removed by a chemical polishing process, a physical polishing process, or both.

When performing the chemical polishing process, the low-k layer may be removed by a solution having a base. After the fluoride treatment, the Si—O bond in the low-k layer is broken or is on the verge of breaking, so that the base in the solution easily reacts with silicon or oxygen. Accordingly, the low-k layer is dissolved into the solution having a base, thereby removing the low-k layer from the object.

For example, the solution having a base includes pure water in which an inorganic base is dissolved. An example of the inorganic base includes sodium hydroxide, ammonium hydroxide, potassium hydroxide, etc. These can be alone or in combinations thereof.

When a concentration of the solution having a base is below about 0.1M, the low-k layer is not sufficiently removed from the object, and when a concentration of the solution having a base is above about 2M, the solution having a base causes damage to the object. In addition, the solution having a base with a concentration above about 2M is disadvantageous regarding manufacturing costs. Accordingly, the concentration of the solution having a base preferably ranges from about 0.1M to about 2M.

The solution having a base may include an organic solvent in which an organic base is dissolved. Examples of the organic base include hydroxylamine, diethanolamine, triethanolamine, etc. These can be use alone and in combinations thereof. Examples of the organic solvent include xylene, methyethyketone, cyclohexanone, 2-heptanone, 3-heptanone, 4-heptanone, ethyleneglycolmonomethylether, ethyleneglycolmonoeethylether, methylcellosolveacetate, ethylcellosolveacetate, diethyleneglycolmonomethylether, diethyleneglycolmonoethylether, propyleneglycolmethyletheracetate, propyleneglycolpropyletheracetate, diethyleneglycoldimethylether, ethyl lactate, etc. These can be use alone and in combinations thereof.

The solution having a base may further include a volatile organic solvent. The volatile organic solvent accelerates the removal of the low-k layer from the object. Examples of the volatile organic solvent include benzene, toluene, alcohol, acetone, etc. These can be used alone or in combinations thereof. In the present embodiment, acetone is used as the volatile organic solvent.

When performing the physical polishing process, the low-k layer is removed from the object by a brushing process. The low-k layer may be brushed simultaneously with a volatile organic solvent to be readily removed from the object. In the present embodiment, the low-k layer is immersed in a volatile organic solvent prior to brushing the low-k layer. The volatile organic solvent is described above, thus any further detailed description on the volatile organic solvent is omitted.

Then, a cleaning process may be optionally performed on the object (step S30). Accordingly, the low-k layer is effectively removed from the object.

Method of Recycling a Wafer

Hereinafter, a method of recycling a wafer using the above method will be described in detail.

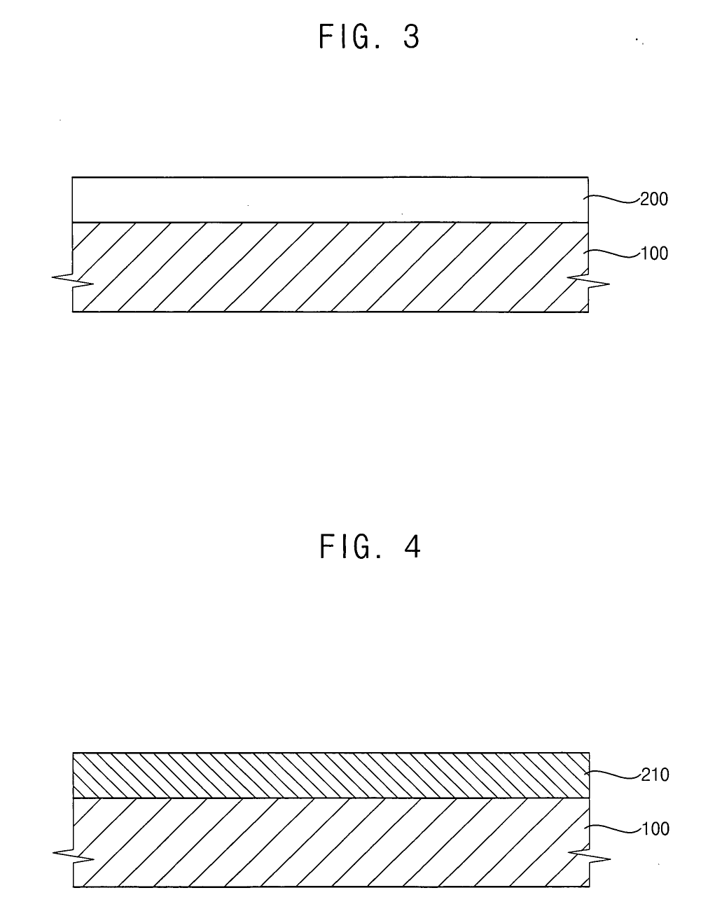

FIGS. 3 to 5 are cross-sectional views illustrating processing steps for a method of recycling a wafer according to an example embodiment of the present invention.

Referring to FIG. 3, a low-k layer 200 is formed on a wafer 100. The low-k layer 200 may comprise an organic silicon compound. Examples of the organic silicon compound include a carbon doped silicon oxide (SiCOH), hydrogenated silicon carbide, etc. These can be used alone or in combinations thereof. The low-k layer 200 is very hard compared to a conventional silicon oxide layer such as a silicon dioxide (SiO2) layer and is very difficult to remove from the wafer 100.

Referring to FIG. 4, a fluoride treatment is performed on the low-k layer 200, thereby forming a fluoride-treated low-k layer 210 on the wafer 100 using an aqueous hydrogen fluoride solution. A concentration of the aqueous hydrogen fluoride solution is in a range of from about 20% to about 50% by volume, and more particularly, in a range of from about 30% to about 50% by volume. In the solution, almost all the hydrogen fluoride is changed into ions, so that the Si—O bond in the fluoride-treated low-k layer 210 is broken or is on the verge of breaking the bond due to the proton donating ability of the ions. Accordingly, the fluoride-treated low-k layer 210 is easily removed from the wafer 100 in a subsequent process.

In the present embodiment, the wafer 100 including the fluoride-treated low-k layer 210 is immersed into the aqueous hydrogen fluoride solution at a temperature of about 20° C. to about 60° C. for a time of about one minute to about thirty minutes, thereby performing the fluoride treatment on the low-k layer 200.

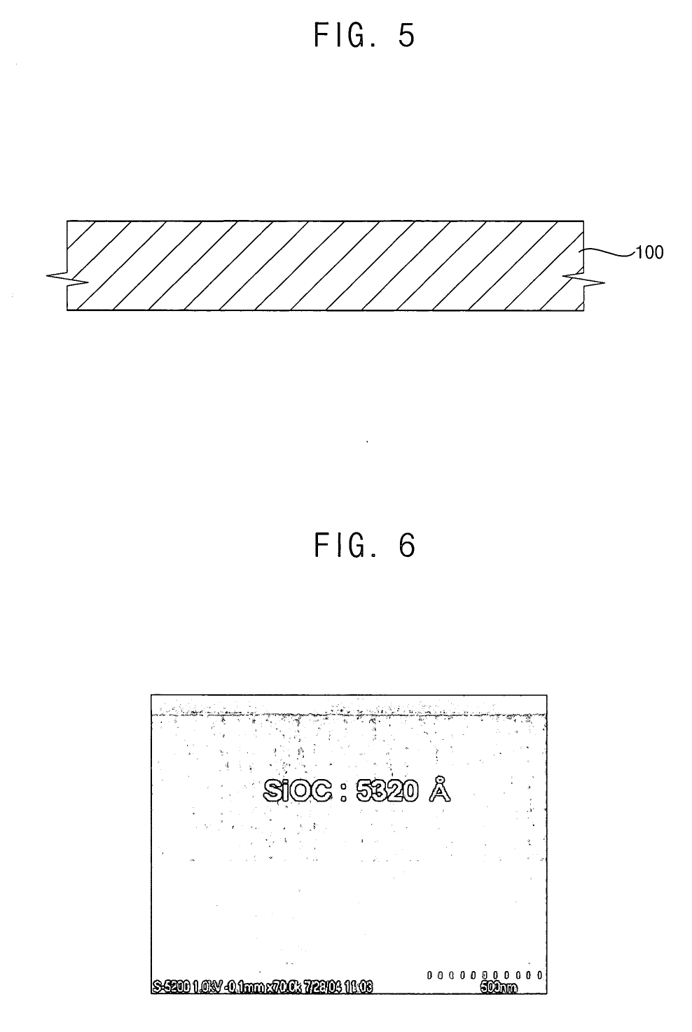

Referring to FIG. 5, the fluoride-treated low-k layer 210 is removed from the wafer 100 by a chemical polishing process, a physical polishing process, or both.

When performing the chemical polishing process, the fluoride-treated low-k layer 210 may be removed from the wafer 100 by a solution having a base. A concentration of the solution having a base ranges from about 0.1M to about 2M. The solution having a base may further include a volatile organic solvent. The volatile organic solvent is described above, thus any further detailed description on the volatile organic solvent is omitted.

When performing the physical polishing process, the fluoride-treated low-k layer 210 is removed from the wafer 100 by a brushing process. The fluoride-treated low-k layer 210 may be brushed simultaneously with a volatile organic solvent to easily remove the fluoride-treated low-k layer 210 from the wafer 100. In the present embodiment, the fluoride-treated low-k layer 210 is immersed in a volatile organic solvent prior to brushing the fluoride-treated low-k layer 210.

Then, a cleaning process may be optionally performed on the wafer. Accordingly, the fluoride-treated low-k layer 210 is effectively removed from the wafer 100.

Experiment on Removal of the Low-k Layer

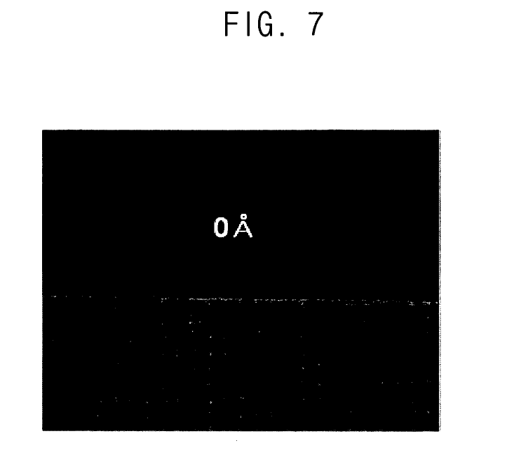

FIG. 6 is an electron microscope photograph showing a sample wafer on which a low-k layer is formed, and FIG. 7 is an electron microscope photograph showing the sample wafer from which the low-k layer is removed in accordance with the same process as described with reference to FIG. 1.

Referring to FIGS. 6 and 7, a sample wafer on which a low-k layer comprising carbon doped silicon oxide was formed to a thickness of about 5320 Å was immersed in an aqueous hydrogen fluoride solution with a concentration of about 30% by volume for a time of about ten minutes at room temperature. Then, the sample wafer was treated by acetone, and the low-k layer was removed from the sample wafer using an aqueous ammonium hydroxide (NH4OH) solution. As shown in FIG. 7, the low-k layer was sufficiently removed from the sample wafer.

According to some embodiments of the present invention, the Si—O bond in the low-k layer is broken or is on the verge of breaking the bond due to an aqueous hydrogen fluoride solution, so that the low-k layer is easily removed from the wafer in a subsequent process. Accordingly, the wafer may be recycled at a low cost without performing any high temperature processes, thereby improving manufacturing productivity of a semiconductor.

Although the exemplary embodiments of the present invention have been described, it is understood that the present invention should not be limited to these exemplary embodiments but various changes and modifications can be made by one skilled in the art within the spirit and scope of the present invention as hereinafter claimed.

What is claimed is:

1. A method of removing a low-k layer, comprising:
performing a fluoride treatment on the low-k layer formed on an object using an aqueous hydrogen fluoride solution; and
removing the low-k layer from the object.

2. The method of claim 1, wherein the low-k layer comprises an organic silicon compound.

3. The method of claim 2, wherein the organic silicon compound includes any one selected from the group consisting of carbon doped silicon oxide (SiCOH), hydrogenated silicon carbide (SiCH), and a combination thereof.

4. The method of claim 1, wherein a concentration of the aqueous hydrogen fluoride solution ranges from about 20% by volume to about 100% by volume.

5. The method of claim 4, wherein the concentration of the aqueous hydrogen fluoride solution ranges from about 30% by volume to about 90% by volume.

6. The method of claim 5, wherein the concentration of the aqueous hydrogen fluoride solution ranges from about 30% by volume to about 50% by volume.

7. The method of claim 1, wherein performing the fluoride treatment on the low-k layer includes immersing the object on which the low-k layer is formed in the aqueous hydrogen fluoride solution.

8. The method of claim 7, wherein the aqueous hydrogen fluoride solution is at a temperature of about 20° C. to about 60° C.

9. The method of claim 7, wherein the object is immersed in the aqueous hydrogen fluoride solution for a time of about one minute to about thirty minutes.

10. The method of claim 1, wherein the low-k layer is removed from the object by at least one of a chemical polishing process, a physical polishing process.

11. The method of claim 10, wherein the chemical polishing process is performed using a solution having a base.

12. The method of claim 11, wherein a concentration of the solution including the base ranges from about 0.1M to about 2M.

13. The method of claim 11, wherein the solution having the base includes pure water in which inorganic base is dissolved.

14. The method of claim 13, wherein the inorganic base includes any one selected from the group consisting of sodium hydroxide, ammonium hydroxide, potassium hydroxide, and combinations thereof.

15. The method of claim 11, wherein the solution having the base includes an organic solvent in which organic base is dissolved.

16. The method of claim 15, wherein the organic base includes any one selected from the group consisting of hydroxylamine, diethanolamine, triethanolamine, and combinations thereof.

17. The method of claim 15, wherein the organic solvent includes any one selected from the group consisting of xylene, methyethyketone, cyclohexanone, 2-heptanone, 3-heptanone, 4-heptanone, ethyleneglycolmonomethylether, ethyleneglycolmonoeethylether, methylcellosolveacetate, ethylcellosolveacetate, diethyleneglycolmonomethylether, diethyleneglycolmonoethylether, propyleneglycolmethyletheracetate, propyleneglycolpropyletheracetate, diethyleneglycoldimethylether, ethyl lactate, and a combination thereof.

18. The method of claim 11, wherein the solution having a base further includes a volatile organic solvent.

19. The method of claim 18, wherein the volatile organic solvent includes any one selected from the group consisting of benzene, toluene, alcohol, acetone, and combinations thereof.

20. The method of claim 10, wherein the physical polishing process includes a brushing process against the low-k layer.

21. The method of claim 20, wherein the brushing process is performed concurrently with a treatment by a volatile organic solvent.

22. A method of recycling a wafer, comprising:
performing a fluoride treatment on a low-k layer formed on a wafer using an aqueous hydrogen fluoride solution; and
removing the low-k layer from the wafer by at least one of a chemical polishing process, a physical polishing process.

23. The method of claim 22, wherein a concentration of the aqueous hydrogen fluoride solution ranges from about 20% by volume to about 100% by volume.
